(19) United States
(12) Patent Application Publication
(10) Pub. No.: US 2016/0268970 A1
(43) Pub. Date: Sep. 15, 2016

(54) SENSITIVITY VARIABLE LOOP GAIN OSCILLATOR SENSOR SYSTEM

(71) Applicant: Fred Mirow, Lower Merion, PA (US)

(72) Inventor: Fred Mirow, Lower Merion, PA (US)

(21) Appl. No.: 15/065,847

(22) Filed: Mar. 9, 2016

Related U.S. Application Data
(60) Provisional application No. 62/131,243, filed on Mar. 10, 2015.

(51) Int. Cl. H03B 5/12; H03B 5/04

(52) U.S. Cl. CPC H03B 5/1234; H03B 5/04; H03B 2200/0086

(57) ABSTRACT

A sensor system on an oscillator having variable loop gain level is described. Only when the oscillator loop gain is at least the level of one does the oscillator produce an AC output signal. The oscillator's ability to oscillate is controlled by the one or more sensor/transducer input signal levels which controls the Q level of an element in a resonate circuit which with other components forms a feedback network.

### CROSS-REFERENCE TO RELATED APPLICATIONS

The benefits of filing this invention as Provisional application for patent “IMPROVED SENSITIVITY VARIABLE LOOP GAIN OSCILLATOR SENSOR SYSTEM”, U.S. PTO 62/131,243 filed 10 Mar. 2015 by Fred Mirow are claimed.

### BACKGROUND OF THE INVENTION

This invention relates to sensor systems for detecting the presence of material based on variable loop gain oscillators and is described. Only when the oscillator's loop gain level is at least one does the oscillator produces an AC signal. The oscillator ability to oscillate is controlled by the one or more sensor and or transducer input signal levels. The system's output signal depends on whether the oscillator is oscillating or not, or the oscillator's AC signal level required to just maintain oscillation. Additional input signals may also be applied such as to compensate for temperature variations and make measurements.

Transducers and sensors have often been used to provide the input signals for many forms of prior art transducer instrumentation, for example, scales or balances, accelerometers, and pressure transducers or proximity gauges. In such systems, the precision at which measurements or material detection can be made is very much a function of the stability of the circuit interfacing the sensor portion and read-out-portion of the system. For the purposes of this invention the term sensor refers to both transducers and sensors.

More particularly, the class of system exemplified by Fred Mirow in U.S. Pat. No. 7,456,700 titled “Variable loop gain oscillator system”. This invention increases system accuracy by making the accuracy dependent on passive component ratios instead of transistor or signal frequency stability.

The objective of the present invention is to provide a sensor system with the advantages of the previous invention along with increased input signal sensitivity.

### BRIEF SUMMARY OF THE INVENTION

According to this invention, one or more sensors, this term also includes transducers, having a variable “Q” level controlled by a physical or electrical parameter of interest, such as voltage, current, displacement, vibration, spacing, size, pressure and the like, are used along with other components to form an oscillator. The sensor uses a component of the tuned circuit. The sensor functions by varying the “Q” level of the tuned circuit. As the “Q” level varies the tuned circuit impedance varies. In most practical cases, the “Q” level of the tuned circuit is the “Q” level of the capacitor or inductor with the lowest “Q” level. The “Q” level is the capacitor or inductor reactance level divided by its resistance level.

An oscillator is formed by connecting a feedback network section to an amplifier section. The feedback network is connected to the input and output of the amplifier so as to provide positive feedback and be capable of oscillating. The amplifier has a phase shift of about 0 degrees, the feedback network supplies the remaining phase shift necessary to make the total phase shift at the frequency of oscillation 0 degrees. If the amplifier is phase inverting having a phase shift of about −180 degrees, than the feedback network would provide the required phase shift amount to have 0 degrees total. The feedback network phase shift and gain vary with signal frequency. The feedback network includes a resonate circuit along with other components. There are many well known phase shift networks that can be used as part of feedback network that have inductor and capacitor combinations that form resonate circuits.

This oscillator will only oscillate when the loop gain level of the amplifier and feedback network is at least one and the phase shift is zero. The oscillator state can readily be detected. When oscillating an AC signal is present and when not oscillating, no AC signal is present. This AC signal may also directly be used as a output signal indicating the loop gain level or a detector can be connected to the oscillator to provide the desired type of output signal, indicating if the AC signal is present or not and in some cases the level of the AC signal.

An output signal level indicating the input signal level of the sensor can also be obtained by changing the oscillator loop gain level in response to both the sensor input signal level and a gain control signal value and monitoring whether the oscillator is oscillating or not. The value of the gain control signal represents the sensor's input signal level when the oscillator's AC signal level is changed from not zero to zero or vice a versa.

It is also possible to provide an output signal level representing a sensor input signal level by making the gain control signal level proportional to the oscillator's AC signal level. By using the sensor input signal and a gain control signal so that both signals control the oscillator's loop gain level. As the input sensor signal level changes the loop gain level, the AC signal level also changes. As the oscillator's AC signal level increases, the gain control signal level changes to decrease the oscillator's AC signal level. This negative feedback just maintains oscillation, keeping the loop gain level at or close to one. The gain control signal value therefore indicates the sensors input signal level.

The amplifier section has a high temperature and voltage stability due to its reliance on negative feedback and or component ratios to set circuit thresholds operating values. Resistor networks can be used in the amplifier section to increase phase and gain stability against the effects of temperature and voltage. One well known approach is to use a high gain amplifier which uses negative feedback to accurately set the amplifier section's gain level. The negative feedback is optimally obtained by using a resistor divider network in which the resistor temperature and voltage characteristics are matched. The effects of temperature on the resistor network are then decreased. This also decreases the effects on the amplifier section since the gain of it is primarily determined by the resistor divider network. Another approach is to use a transistor to form a source or emitter follower amplifier.

The feedback network uses a resonate circuit in which the “Q” level of one or more of the sensors in this resonate circuit is varied by the sensor input signal level. As the “Q” level varies, the resonate circuit impedance also varies. This resonate circuit is used with a resistance to form a signal divider network. As the “Q” level varies the signal level out of the feedback network varies.

The “Q” level of an inductive based sensor is affected by proximity to conductive objects and also by the permittivity variation of its core when a magnetic material core is used. A capacitive based sensor “Q” level is affected by proximity to objects that cause a change in dielectric loss. An example is the change in dielectric material from dry air to salty water.

It is understood that resonate circuits can also be obtained by using a capacitor or inductor based sensor in combination with a circuit containing resistors and one or more amplifiers. These circuits are well known in the field of active filters. It is also understood series resonate or parallel resonate circuits can be used along with current and voltage input signal amplifiers without changing the principles of this sensor systems operation.

### BRIEF DESCRIPTION OF THE DRAWINGS

Reference will be made in detail to preferred embodiments of the invention, examples of which are illustrated in the accompanying drawings. The drawings are intended to be illustrative, not limiting. Although the invention will be described in the context of these preferred embodiments, it should be understood that it is not intended to limit the spirit and scope of the invention to these particular embodiments.

FIG. 1 shows a block diagram of sensor system 1;

FIG. 2 shows a block diagram of sensor oscillator 10A;

FIG. 3; shows a block diagram of sensor oscillator 10B;

FIG. 4 shows a block diagram of calibrated sensor oscillator 10C;

FIG. 5 shows a diagram of feedback network 2C and;

FIG. 6; shows a block diagram of sensor oscillator 10D.

### DETAILED DESCRIPTION OF THE INVENTION

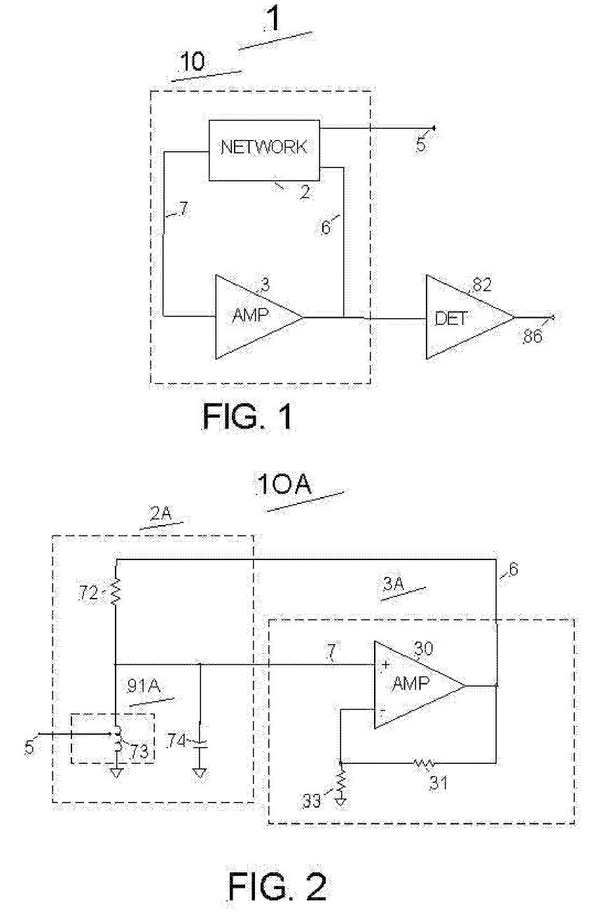

An embodiment of the invention is shown in FIG. 1. The sensor system 1 comprising feedback sensor oscillator 10, and detector 82. Sensor oscillator 10 is formed by feedback network 2 being connected to the input and output of amplifier 3 by lines 7 and 6 so as to be capable of oscillating. Feedback network 2 receives “Q” control signals from input 5. The output of amplifier 3 is also connected to detector 82 input. The output signal of detector 82 is at output 86. An AC signal is present on lines 6 and 7 only when the sensor oscillator 10 is oscillating. The feedback network 2 phase shift and gain level vary with the AC signal frequency. Detector 82 indicates AC signal level and or whether or not an AC signal is present on line 6. Detector 82 converts the signal on line 6 to the type of output signal desired at output 86, which for example can be a digital signal. It is understood that Detector 82 could convert the signal on line 7 instead of line 6.

As the signal level of input 5 varies and changes the loop gain level of feedback network 2 and amplifier 3 lower than the value of one, sensor oscillator 10 stops oscillating. The AC signal level on line 6 at the detector 82 input becomes zero and the digital signal at terminal 86 changes state, for example from a high to a low level. Thus the digital signal at terminal 86 is controlled by the signal level of input 5.

An embodiment of sensor oscillator 10 is shown in FIG. 2. The sensor oscillator 10A is implemented by feedback network 2A and amplifier 3A. Amplifier 3A is shown implemented using an OP-AMP with gain setting resistors. The output of OP-AMP 30 is connected to line 6 and its positive input is connected to line 7. Its negative input is connected to one end of resistors 31 and resistor 33. The other end of resistor 31 is connected to line 6 and the other end of resistor 33 is connected to ground. The gain level of amplifier 30 is primarily a function of the resistance ratio of resistor 31 and resistor 33 since the gain of OP-AMP 30 is much greater than the gain set by the resistors 31 and resistor 33. Feedback network 2A provides phase shift and gain dependant on signal frequency. The input signal to feedback network 2A is connected by line 6 and the output signal is applied to line 7. Resistor 72 is connected between line 6 and line 7. Line 7 is also connected to sensor 91A and capacitor 74. The other side of sensor 91A and capacitor 74 are connected to ground.

Sensor 91A is implemented by inductor 73. The “Q” of inductor 73 is varied by the signal at input 5. Inductor 73 and capacitor 74 form a tuned circuit. The signal at input 5 may be for example the distance of a copper plate to inductor 73. As the “Q” of inductor 73 is varied the impedance between line 7 and ground is varied which causes the signal level ratio of line 6 to line 7 to also vary. As the signal level ratio of line 6 to line 7 varies the loop gain of amplifier 3A and feedback network 2A varies. The loop gain level determines the level of AC signal on line 6. The AC signal level is zero when the loop gain level is less than one.

It is also understood that capacitor 74 could be replaced by a capacitive sensor that works by varying the material placed near or inserted between the capacitors plates. As the “Q” of a capacitive sensor that replaced capacitor 74 is varied the impedance between line 7 and ground is varied.

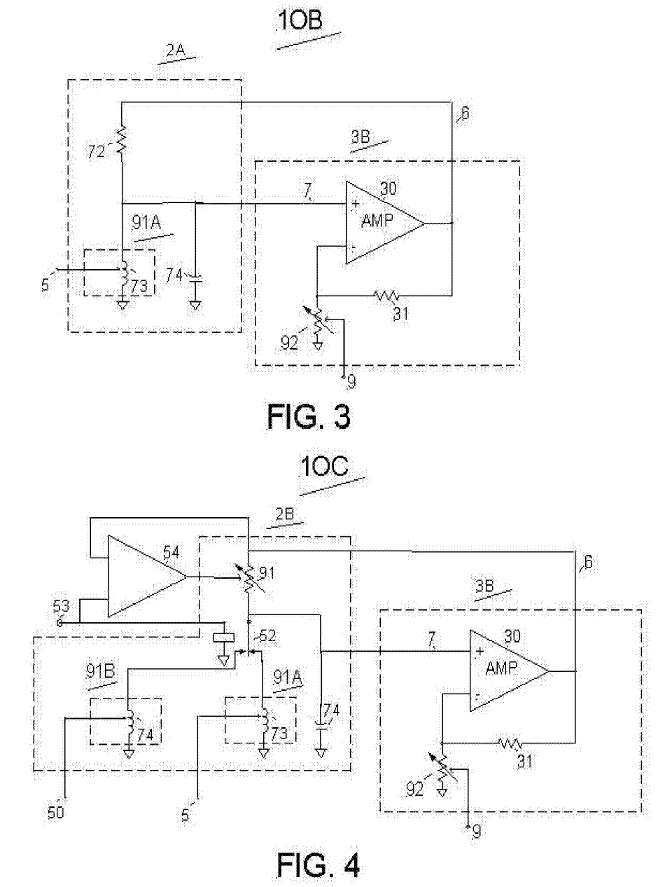

Referring now to FIG. 3, is sensor oscillator 10B which provides an output, which may be digital, representing the value of the signal level at input 5. Sensor 91A output along with the resistance value of variable resistor 92 varies the oscillator loop gain level. The resistance value of variable resistor 92 is controlled by a gain control signal input signal at input 9. As the resistance value of resistor variable 92 is varied the oscillator loop gain level is also varied.

The AC signal level on line 6 changes when the sensor oscillator 10B loop gain level increase above or decreases below the minimum loop gain value for oscillation to occur. The level of oscillator 10B loop gain is a function of both the sensor 91A at input 5 and gain control signal at input 9. Since the input 9 signal also controls the level of sensor oscillator 10B loop gain, the input 9 signal value indicates the signal level of input 5 when the change from presence to absence or vice a versa of an AC signal occurs on line 6.

Temperature compensation can be added by adding a temperature sensor that provides an additional gain control signal to variable resistor 92 or a different variable resistor that replaces resistors 72 and or 31. The level of sensor oscillator 10B loop gain is now also responsive to the temperature sensor output signal level which is applied to increase sensor oscillator 10B temperature stability. It is also understood that the temperature sensor and variable resistor can be one and the same by using a temperature sensing resistor such as a thermistor.

In addition the gain control signal input signal at input 9 may be made responsive to the AC signal level on line 6. The gain control signal input signal now provides negative feedback to sensor oscillator 10B to just maintain oscillation. The gain control signal input signal level at input 9 now indicates the input 5 signal levels.

It is also understood that resistors 72 and or 31 could be replaced by variable resistors responsive to the gain control signal at input 9 instead of variable resistor 92. Also, additional gain control signals can be applied to different variable resistors.

Referring now to FIG. 4, is calibrated sensor oscillator 10C which uses feedback network 2B to operate in either calibration mode or sense mode as determined by mode control input 53. Mode control input 53 signal is applied to relay 52 and loop gain controller 54. A known input signal level is applied to sensor 91B input on line 50. When in calibration mode, relay 52 disconnects sensor 91A output and connects sensor 91B output to line 7. Sensor 91A and sensor 91B ideally are nearly identical in performance, for example matching temperature drift. The sensor oscillator 10C loop gain level is responsive to the sensor 91B output signal level and also the Loop gain controller 54 output level. Loop gain controller 54 output level is responsive to the line 6 AC signal level compared to a predetermined value. The line 6 AC signal level is responsive to the sensor oscillator 10C loop gain level. Loop gain controller 54 output signal level varies the resistance value of variable resistor 91 to adjust the sensor oscillator 10C loop gain so that the sensor oscillator 10C loop gain is proportional to the sensor 91B input signal level.

When in sense mode relay 52 disconnects sensor 91B output and connects sensor 91A output to line 7. The sensor oscillator 10C loop gain level is responsive to the sensor 91A output signal level and also the Loop gain controller 54 output level. Loop gain controller 54 output level is now not responsive to the line 6 AC signal level and maintains the last calibration mode operation output signal level. This causes the resistance value of variable resistor 91 to remain constant in the sense mode.

Input 5 varies sensor 91A output which now varies the sensor oscillator loop gain level that has been adjusted by the Loop gain controller 54 output level. Since both Sensor 91A and sensor 91B both vary the sensor oscillator loop gain level the output signal levels of Sensor 91A and sensor 91B are compared to determine the line 6 AC signal level. This permits variations in the output signal levels of Sensor 91A and sensor 91B, such as caused by temperature variation, to be cancelled out.

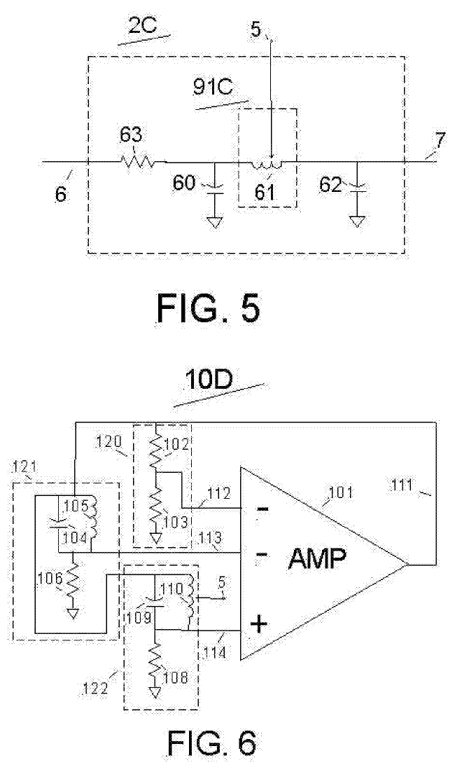

Another embodiment of feedback network 2 is shown in FIG. 5. Feedback network 2C is used to provide 180 degrees phase shift. The phase shift and signal gain level are dependent on frequency.

The input signal to feedback network 2C is connected by line 6 and the output signal is applied to line 7. Resistor 63 is connected between line 6 and sensor 91C and capacitor 60. Line 7 is connected to sensor 91C and capacitor 62. The other sides of capacitors 60 and 62 are connected to ground.

Sensor 91C is implemented by inductor 61. The “Q” of inductor 61 is varied by the signal at input 5. The signal at input 5 may be generated for example by the proximity of a copper plate brought near inductor 61. As the “Q” of inductor 61 is varied the signal level ratio of line 6 to line 7 to also varies.

Another embodiment of sensor oscillator 10 is shown in FIG. 6 sensor oscillator 10D. Sensor oscillator 10D is formed by feedback network 120 being connected to the first inverting input and output of amplifier 101 by lines 111 and 112, feedback network 121 being connected to the second inverting input and output of amplifier 101 by lines 111 and 113, and feedback network 122 being connected to the non inverting input and output of amplifier 101 by lines 111 and 114 so as to be capable of oscillating. Feedback network 122 receives “Q” control signals from input 5. An AC signal is present on lines 111 only when the sensor oscillator 10D is oscillating.

Feedback network 120 is formed by connecting both resistors 102 and 103 to line 112. The other end of resistor 102 is connected to line 111 and the other end of resistor 103 is connected to ground.

Feedback network 121 is formed by connecting both capacitor 104 and inductor 105 to line 111. The other end of both capacitor 104 and inductor 105 is connected to line 113. Resistor 106 is connected between line 113 and ground.

Feedback network 122 is formed by connecting both capacitor 74A and inductor 73A to line 111. The other end of both capacitor 74A and inductor 73A is connected to line 114. Resistor 108 is connected between line 114 and ground.

The feedback networks 121 and 122 phase shift and gain level vary with the AC signal frequency. The phase shift and gain level of feedback network 122 is also varied by the input signal level on line 5.

The temperature sensitivity of Sensor oscillator 10D is reduced by having the temperature response of feedback networks 121 and 122 similar. By applying the outputs of feedback networks 121 and 122 to the inverting and non inverting inputs of amplifier 101 the changes caused by temperature are mostly cancelled out.

Although the above description has been directed to preferred embodiments of the invention, it will be understood and appreciated by those skilled in the art that other variations and modifications may be made without departing from the spirit and scope of the invention, and therefore the invention includes the full range of equivalents of the features and aspects set forth in the appended claims.

I claim:

1. A sensor system providing an output signal level dependant on an input signal level comprising;
an amplifier to provide signal gain,
a first feedback network to provide negative feedback from said amplifier output to said amplifier input,
a second feedback network to provide positive feedback from said amplifier output to said amplifier input,
said first or second feedback network includes a resonate circuit, while other said first or second feedback network provides a constant gain level feedback from said amplifier output to said amplifier input,
said resonate circuit impedance level responsive to proximity of external objects,
said impedance level controls gain level of said first or second feedback network,
said amplifier having loop gain level responsive to said impedance level, and
said amplifier oscillating to produce an AC output signal with said AC output signal level responsive to said loop gain level.

2. A sensor system with increased temperature stability providing an output signal level dependant on an input signal level comprising;
an amplifier to provide signal gain,
a first feedback network to provide a constant gain level negative feedback from said amplifier output to said amplifier input,
a second feedback network to provide positive feedback from said amplifier output to said amplifier input,
said second feedback network includes a first resonate circuit,
a third feedback network to provide negative feedback from said amplifier output to said amplifier input,
said third feedback network includes a second resonate circuit,
gain of said second feedback network has temperature dependency similar to gain of said third feedback network,
said first or second resonate circuit having said resonate circuit impedance level responsive to proximity of external objects,
said impedance level controls gain level of said second or third feedback network,
said amplifier having loop gain level responsive to said second and third feedback networks,
said amplifier having loop gain level having temperature effects reduced by said second and third feedback network, and
said amplifier oscillating to produce an AC output signal with said AC output signal level responsive to said loop gain level.

3. The invention of claim 2 wherein said first resonate circuit impedance level IS responsive to proximity of external objects, and
said second resonate circuit impedance level is responsive to proximity of external objects.
